(19) United States
(12) Patent Application Publication
(10) Pub. No.: US 2022/0162737 A1
(43) Pub. Date: May 26, 2022

(54) SYSTEMS AND METHODS FOR IN-SITU ETCHING PRIOR TO PHYSICAL VAPOR DEPOSITION IN THE SAME CHAMBER

(71) Applicant: OEM Group, LLC, Gilbert, AZ (US)

(72) Inventors: Marc-Andre Lariviere, Mesa, AZ (US); Juan M. Rios Reyes, Exeter, CA (US); Nitin Choudhary, Mesa, AZ (US); Chao Li, Chandler, AZ (US); Brendan V. Trang, La Puente, CA (US)

(73) Assignee: OEM Group, LLC, Gilbert, AZ (US)

(21) Appl. No.: 17/517,626

(22) Filed: Nov. 2, 2021

Related U.S. Application Data
(60) Provisional application No. 63/118,343, filed on Nov. 25, 2020.

(51) Int. Cl. C23C 14/02; C23C 14/35; C23C 14/06

(52) U.S. Cl. CPC C23C 14/022; H01J 37/3405; C23C 14/0617; C23C 14/35

(57) ABSTRACT

The present invention provides a method for in-situ etching of a wafer prior to physical vapor deposition, the method comprising the following steps. A sputtering chamber is provided, the sputtering chamber being collectively defined by a wafer handling apparatus and a magnetron. The wafer is placed into the sputtering chamber. A gas is introduced into the sputtering chamber such that the gas is separated into a plasma, wherein the plasma includes gas ions. A first negative potential is applied to the wafer using a wafer chuck of the wafer handling apparatus while a second negative potential is simultaneously applied to a sputtering target of the magnetron, wherein simultaneous application of the first negative potential to the wafer and the second negative potential to the sputtering target causes gas ions to eject material from the wafer and the sputtering target of the magnetron such that ejected material from the wafer and the sputtering target is collected onto a shield defined by the sputtering chamber.

### CROSS REFERENCES TO RELATED APPLICATIONS

This application claims priority from and is related to commonly owned U.S. Provisional Patent Application Ser. No. 63/118,343 filed Nov. 25, 2020, entitled: SYSTEMS AND METHODS FOR IN-SITU ETCHING PRIOR TO PHYSICAL VAPOR DEPOSITION IN THE SAME CHAMBER, this Provisional Patent Application incorporated by reference herein.

### FIELD OF THE INVENTION

The present disclosure generally relates to wafer etching and processing techniques; and in particular to a system and associated method for in-situ dry etching of a substrate.

### BACKGROUND OF THE INVENTION

Prior to physical vapor deposition (PVD) of a material onto a wafer or substrate, it is often advantageous to remove surface impurities using an etching process. Traditionally, separate etching and PVD equipment are respectively used for etching and physical vapor deposition. Etched wafers must be transported to separate equipment between etching and PVD processes, thereby reducing throughput and requiring maintenance, physical space and running costs for separate etch and deposition chambers. One reason that etching and PVD processes have traditionally been performed separately is that during etching, surface contaminants such as native oxide are often released into the processing chamber. If PVD is then performed within the same chamber without proper consideration of the etched contaminants, these contaminants are often deposited back onto the wafer, thus having a negative effect on PVD film quality.

Nothing in the prior art provides the benefits attendant with the present invention.

Therefore, it is an object of the present invention to provide an improvement which overcomes the inadequacies of the prior art devices and which is a significant contribution to the advancement of using a magnetron system.

Another object of the present invention is to provide a method for in-situ etching of a wafer prior to physical vapor deposition, the method comprising providing a sputtering chamber; placing the wafer into said sputtering chamber; and applying a first negative potential to the wafer in said sputtering chamber while simultaneously applying a second negative potential to a sputtering target in said sputtering chamber.

Yet another object of the present invention is to provide a method for in-situ etching of a wafer prior to physical vapor deposition, the method comprising providing a sputtering chamber, the sputtering chamber being collectively defined by a wafer handling apparatus and a magnetron; placing the wafer into said sputtering chamber; introducing a gas into said sputtering chamber such that the gas is separated into a plasma, wherein the plasma includes gas ions; and applying a first negative potential to the wafer using a wafer chuck of the wafer handling apparatus while simultaneously applying a second negative potential to a sputtering target of the magnetron, wherein simultaneous application of the first negative potential to the wafer and the second negative potential to the sputtering target causes gas ions to eject material from the wafer and the sputtering target of the magnetron such that ejected material from the wafer and the sputtering target is collected onto a shield defined by the sputtering chamber.

Still yet another object of the present invention is to provide a method for in-situ etching of a wafer prior to physical vapor deposition, the method comprising providing a sputtering chamber, the sputtering chamber being collectively defined by a wafer handling apparatus and a magnetron; placing the wafer into said sputtering chamber; introducing a gas into said sputtering chamber such that the gas is separated into a plasma, wherein the plasma includes gas ions; applying a first negative potential to the wafer using a wafer chuck of the wafer handling apparatus while simultaneously applying a second negative potential to a sputtering target of the magnetron, wherein simultaneous application of the first negative potential to the wafer and the second negative potential to the sputtering target causes gas ions to eject material from the wafer and the sputtering target of the magnetron such that ejected material from the wafer and the sputtering target is collected onto a shield defined by the sputtering chamber; purging the plasma from said sputtering chamber; and depositing a film onto the wafer using a physical vapor deposition process within said sputtering chamber by applying a third negative potential to the sputtering target of the magnetron.

The foregoing has outlined some of the pertinent objects of the present invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

The invention described herein provides systems and methods for improved thin film deposition in a sputtering system without redepositing etch surface contaminants back onto the wafer.

A feature of the present invention is to provide a method for in-situ etching of a wafer prior to physical vapor deposition, the method comprising the following steps. A sputtering chamber is provided. The wafer is placed into the sputtering chamber. A first negative potential is applied to the wafer in the sputtering chamber while a second negative potential is simultaneously applied to a sputtering target in the sputtering chamber. The method can further comprise the step of depositing a film onto the wafer using a physical vapor deposition process within the sputtering chamber by applying a third negative potential to the sputtering target. The method can further comprise the step of depositing an aluminum nitride film using the sputtering target. The first negative potential applied to the wafer can be between 100 watts and 300 watts. The second negative potential applied to the sputtering target can be between 100 watts and 350 watts. Material can be sputtered from the sputtering target onto a shield of the sputtering chamber during the application of the second negative potential to the sputtering target and material can be ejected from the wafer onto the shield of the sputtering chamber during the application of the first negative potential to the wafer. The method can further comprise the step of applying heat to the wafer, wherein a temperature of the heat applied to the wafer is between 300 degrees Celsius and 500 degrees Celsius. The method can further comprise the step of rotating the wafer.

Another feature of the present invention is to provide a method for in-situ etching of a wafer prior to physical vapor deposition, the method comprising the following steps. A sputtering chamber is provided, the sputtering chamber being collectively defined by a wafer handling apparatus and a magnetron. The wafer is placed into the sputtering chamber. A gas is introduced into the sputtering chamber such that the gas is separated into a plasma, wherein the plasma includes gas ions. A first negative potential is applied to the wafer using a wafer chuck of the wafer handling apparatus while a second negative potential is simultaneously applied to a sputtering target of the magnetron, wherein simultaneous application of the first negative potential to the wafer and the second negative potential to the sputtering target causes gas ions to eject material from the wafer and the sputtering target of the magnetron such that ejected material from the wafer and the sputtering target is collected onto a shield defined by the sputtering chamber. The method can further comprise the step of depositing a film onto the wafer using a physical vapor deposition process within the sputtering chamber by applying a third negative potential to the sputtering target of the magnetron. The method can further comprise the step of depositing an aluminum nitride film using the sputtering target of the magnetron. The first negative potential applied to the wafer can be between 100 watts and 300 watts. The second negative potential applied to the sputtering target of the magnetron can be between 100 watts and 350 watts. The method can further comprise the step of applying heat to the wafer, wherein a temperature of the heat applied to the wafer is between 300 degrees Celsius and 500 degrees Celsius. The method can further comprise the step of rotating the wafer.

Yet another feature of the present invention is to provide a method for in-situ etching of a wafer prior to physical vapor deposition, the method comprising the following steps. A sputtering chamber is provided, the sputtering chamber being collectively defined by a wafer handling apparatus and a magnetron. The wafer is placed into the sputtering chamber. A gas is introduced into the sputtering chamber such that the gas is separated into a plasma, wherein the plasma includes gas ions. A first negative potential is applied to the wafer using a wafer chuck of the wafer handling apparatus while a second negative potential is simultaneously applied to a sputtering target of the magnetron, wherein simultaneous application of the first negative potential to the wafer and the second negative potential to the sputtering target causes gas ions to eject material from the wafer and the sputtering target of the magnetron such that ejected material from the wafer and the sputtering target is collected onto a shield defined by the sputtering chamber. The plasma is purged from the sputtering chamber. A film is deposited onto the wafer using a physical vapor deposition process within the sputtering chamber by applying a third negative potential to the sputtering target of the magnetron. The method can further comprise the step of depositing an aluminum nitride film using the sputtering target of the magnetron. The first negative potential applied to the wafer can be between 100 watts and 300 watts. The second negative potential applied to the sputtering target of the magnetron can be between 100 watts and 350 watts. The method can further comprise the step of applying heat to the wafer, wherein a temperature of the heat applied to the wafer is between 300 degrees Celsius and 500 degrees Celsius. The method can further comprise the step of rotating the wafer.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

FIG. 1 is a perspective view showing a system for physical vapor deposition onto an arbitrary wafer including a wafer handling apparatus and a magnetron collectively defining a sputtering chamber;

FIG. 2 is an exploded front view of the system of FIG. 1 showing the wafer handling apparatus defining a wafer chuck engaged with a vertical rod that lowers the wafer chuck above the magnetron;

FIG. 3 is a cross-sectional view of the system of FIG. 1 showing the wafer handling apparatus and the magnetron that collectively define the sputtering chamber;

FIG. 4 is a perspective view showing the magnetron of the system of FIG. 1;

FIG. 5 is a front view showing an internal assembly of the magnetron of FIG. 4;

FIG. 6 is an exploded view showing the internal assembly of FIG. 5;

FIGS. 7A and 7B are perspective views showing respective outer and inner magnet assemblies of the internal assembly of FIG. 5;

FIG. 8 is a perspective view showing the wafer handling apparatus of the system of FIG. 1;

FIG. 9 is a front view showing the wafer handling apparatus of FIG. 8;

FIG. 10 is a bottom perspective view showing the wafer handling apparatus of FIG. 8;

FIG. 11 is a front view showing a wafer chuck of the wafer handling apparatus of FIG. 8;

FIG. 12 is a top perspective view showing the wafer chuck of FIG. 11;

FIG. 13 is a below perspective view showing the heated wafer chuck of FIG. 11;

FIGS. 14A and 14B are respective views of the pin assemblies of the water handling apparatus of FIG. 8 in a “wafer loading” position (FIG. 14A) and a “wafer processing” position (FIG. 14B) with the wafer present;

FIG. 15 is a front view showing a gas assembly associated with an upper frame and a lower frame of the wafer handling apparatus of FIG. 8;

FIG. 16 is a front view showing a thermoelectric assembly and shields of a wafer handling apparatus of FIG. 8; and

FIGS. 17A and 17B are respective partially exploded and assembled side views of the wafer chuck of the wafer handling apparatus of FIG. 8 and a baseplate of the magnetron of FIG. 4.

Corresponding reference characters indicate corresponding elements among the view of the drawings. The headings used in the figures do not limit the scope of the claims.

### DETAILED DESCRIPTION OF THE INVENTION

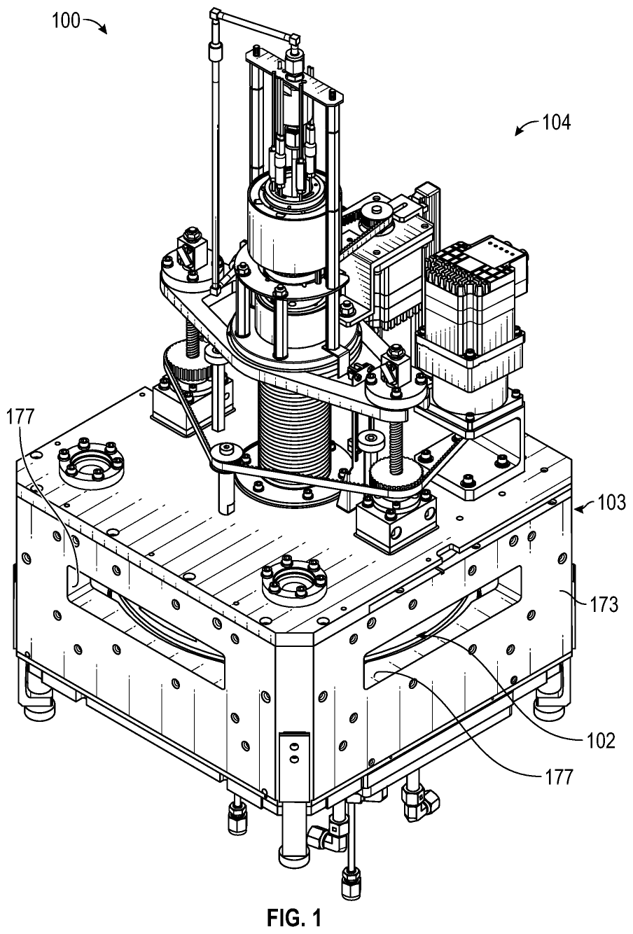

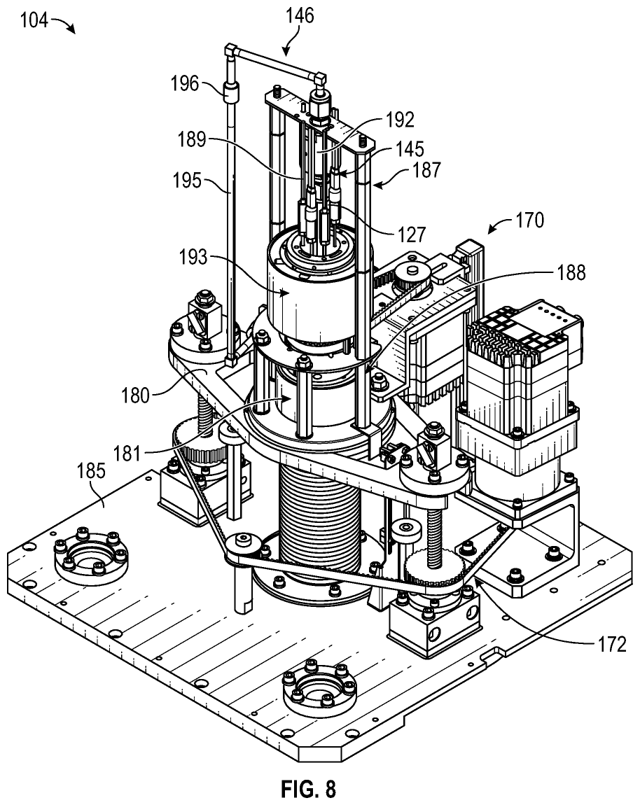

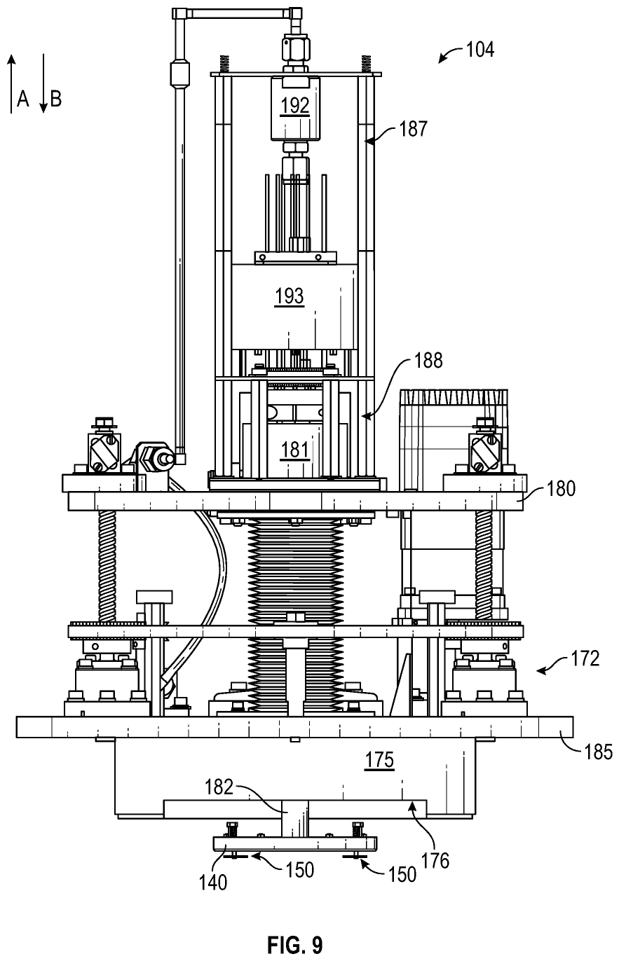

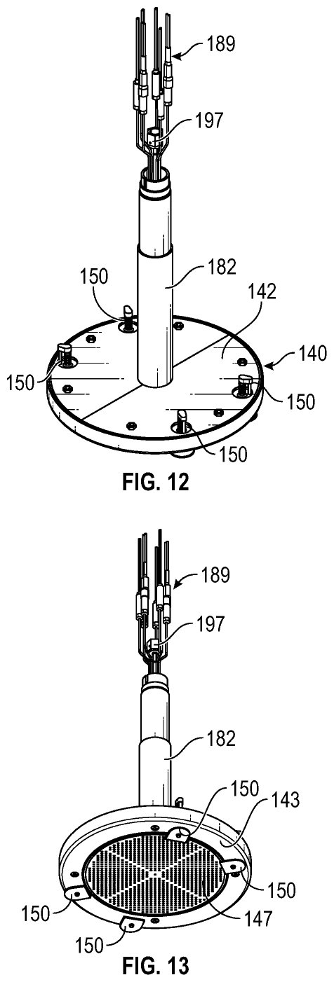

Various embodiments of a system and associated method for in-situ etching of a wafer to remove contaminants prior to AlN film deposition are disclosed herein. In particular, the system includes a magnetron and a lift-and-rotate wafer handling apparatus having a radio frequency (RF) bias-capable wafer chuck collectively defining a sputtering chamber operable for receiving a wafer, applying an in-situ etching process, and then depositing an aluminum nitride (AlN) film onto the wafer. In one aspect, the in-situ etching process includes positioning a wafer against a wafer chuck and above a sputtering target of the magnetron and introducing a plasma into the sputtering chamber. A negative potential in the form of an RF bias is applied to the wafer through the wafer chuck to attract plasma ions to the wafer and etch away surface contaminants while low-level power is simultaneously applied to the magnetron, causing etched surface contaminants to adhere to a shield of the sputtering chamber during the etching process. The etched wafer can then be subjected to AlN film deposition within the sputtering chamber without being transferred to separate equipment and without re-depositing etched surface contaminants back onto the wafer. Referring to the drawings, embodiments of a system for in-situ etching and film deposition are illustrated and generally indicated as 100 in FIGS. 1-17.

### System Overview

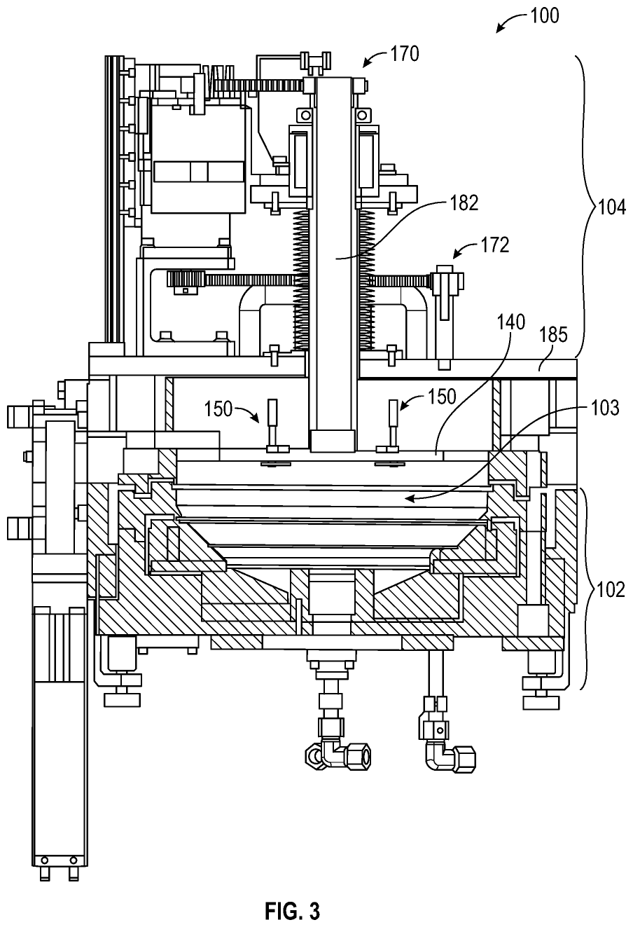

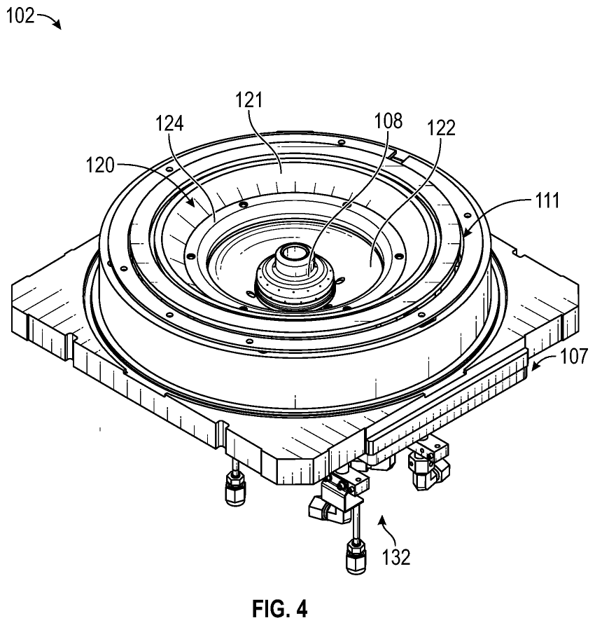

As shown in FIGS. 1-3, a system 100 for in-situ etching of an arbitrary wafer 10 prior to AlN deposition is shown including a magnetron 102 and a wafer handling apparatus 104 positioned above the magnetron 102. In some embodiments, a sputtering chamber 103 is defined as an enclosed space formed below the wafer handling apparatus 104 and above the magnetron 102, as shown in FIG. 3. In some embodiments, the sputtering chamber 103 is enclosed by a sputtering box 173 which may include one or more wafer slots 177 for insertion and removal of the wafer 10 to and from the sputtering chamber 103. As shown, the sputtering chamber 103 includes a shield 175 defined below the wafer handling apparatus. In one method, the wafer 10 is captured against a wafer chuck 140 of the wafer handling apparatus 104 and lowered into the sputtering chamber 103 above the magnetron 102. The wafer chuck 140 is operable for application of a negative potential to the wafer 10 in the form of an RF bias to attract ions towards the wafer 10 for etching contaminants away from the surface (or native oxide layer) of the wafer 10. The magnetron 102 of the system 100 includes a negatively-biased target 120 (FIG. 4) that faces the wafer 10 for repelling etched contaminants away from the target 120 during the in-situ etching process as well as deposition of material from the target 120 onto the wafer 10 following the in-situ etch process.

An inert gas is introduced into the system 100 during the in-situ etch process under ultra-high vacuum such that gas is ionized into positively charged ions by free electrons and these ions are attracted towards the negatively biased wafer 10. When the gas ions strike the surface of the wafer 10, molecules of material are knocked off of the wafer 10. Simultaneously, a low-power negative bias (negative potential) is applied to the magnetron 102 such that molecules of wafer material falling on target 120 by gravity are sputtered/ejected from the target 120 of the magnetron 102 in a similar manner. It is important to note that an amount of power applied to the magnetron 102 during the in-situ etch process is far less than an amount of power applied to the magnetron 102 during regular film deposition. Simultaneous etching of the wafer 10 and light sputtering of material from the target 120 creates an environment within the sputtering chamber 103 such that contaminants etched away from the surface of the wafer 10 are repelled away from the wafer 10 and the target 120 and as a result have nowhere else to adhere but to the shield 175 of the sputtering chamber 103, since the contaminants cannot land back on the wafer 10 or the target 120. In addition, light sputtering of material from the target 120 when low power is applied to the magnetron 102 coats the shield 175 with material such that contaminants are trapped underneath a light layer of material, which prevents outgassing of oxygen and other contaminants into the sputtering chamber 103 during the subsequent film deposition step.

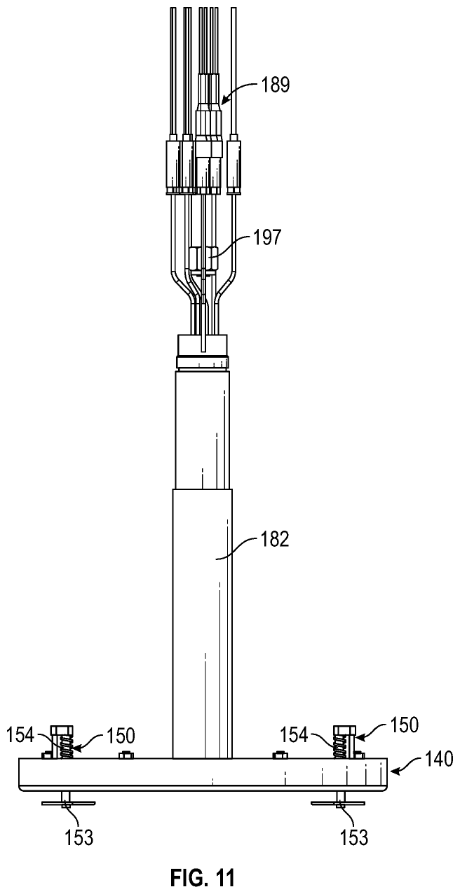

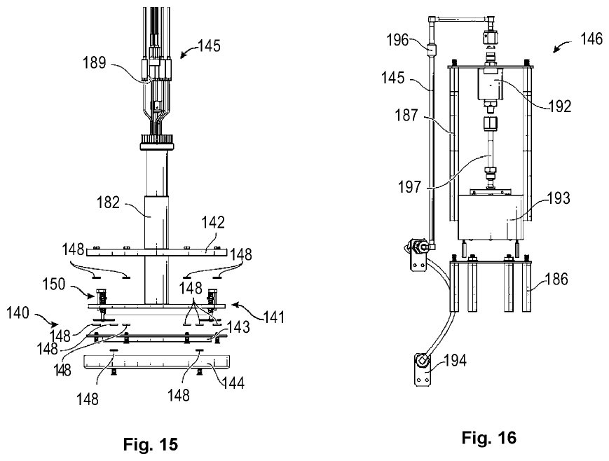

In some embodiments, the wafer handling apparatus 104 of the target system 100 is operable for engaging the wafer 10 and lifting, lowering, and/or rotating the wafer 10 over the target 120 of the magnetron 102 for etching and deposition onto the wafer 10 at controlled height and rotational speed of the wafer 10 relative to the target 120. In some embodiments, the wafer handling apparatus 104 includes a wafer chuck 140 for engaging the wafer 10 and using a plurality of pin assemblies 150 (FIG. 11) to receive the wafer and hold the wafer against and underside of the wafer chuck 140. The wafer chuck 140 also aids in processing the wafer 10 while the wafer 10 is engaged by the wafer chuck 140. In particular, the wafer chuck 140 is operable for delivering a negative potential in the form of an RF bias to the wafer 10 during in-situ etching by thermoelectric assembly 145 (FIG. 15). In some embodiments, the wafer chuck 140 is also operable for applying heat to the wafer 10 during the deposition process through thermoelectric assembly 145.

### Method Overview

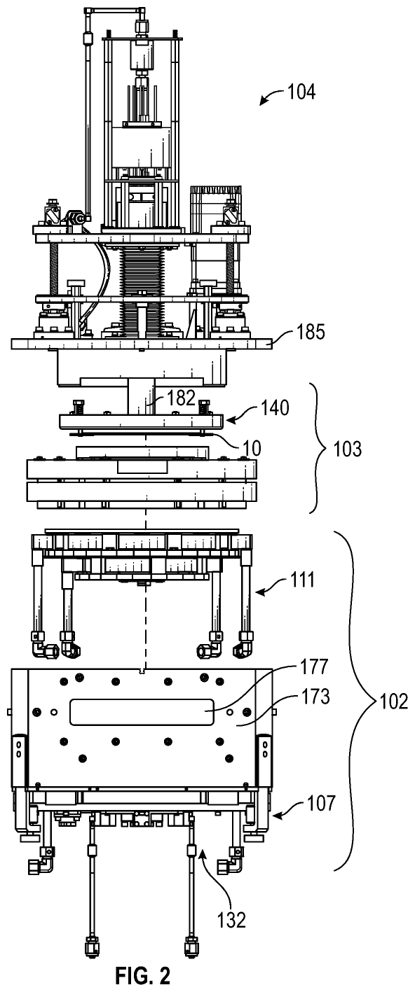

Referring to FIG. 2, the method of in-situ etching of an arbitrary wafer 10 to remove contaminants from a surface of the wafer 10 and trap contaminants to prevent outgassing during a subsequent film deposition step is disclosed herein. The wafer 10 is received by a plurality of pin assemblies 150 (FIG. 11) and secured against the wafer chuck 140 (FIG. 11) of the wafer handling apparatus 104 before being lowered into the sputtering chamber 103 positioned above the magnetron 102. A non-reactive gas is introduced into the sputtering chamber 103 by gas distribution system 132 and is separated into a plasma. In some embodiments, the non-reactive gas is suitable for etching and may include argon gas (5-10 sccm) and nitrogen gas (15-20 sccm). A negative potential in the form of an RF bias (100-300 W) is applied to the wafer 10 via the wafer chuck 140 in association with a thermoelectric assembly 145 (FIG. 15) and low power (100-350 W) is simultaneously applied to the magnetron 102. As discussed above, the RF bias applied to the wafer 10 attracts ions from the plasma towards the surface of the wafer 10 and bombards the surface of the wafer 10, etching away contaminants that are released into the sputtering chamber 103. Similarly, application of low power to the magnetron 102 attracts ions from the plasma towards the target 120 of the magnetron, effectively lightly sputtering material off of the target 120 simultaneously with the etching of the wafer 10. This light sputtering operation simultaneously with application of RF bias to the wafer 10 prevents etched contaminants from landing on and/or adhering to the target 120 or the wafer 10. Thus, etched contaminants are forced to adhere to the shield 175 of the sputtering chamber 103. The application of low power to the magnetron 102 causes light sputtering of material off of the target 120, which also adheres to the shield 175 of the sputtering chamber 103, trapping contaminants underneath a light layer of material from the target 120. This “trapping” mechanism prevents outgassing of oxygen and contaminants from the shield 175 of the sputtering chamber 103 during subsequent film deposition steps, which can subject the sputtering chamber 103 to extremely high temperatures. The gas inside the sputtering chamber 103 is purged several times in order to prepare the etched wafer 10 and sputtering chamber 103 for subsequent film deposition. The wafer 10 is heated (300-500 degrees Celsius) by the wafer chuck 140 associated with the thermoelectric assembly 145. An AlN film is then deposited onto the wafer 10 while a temperature of the wafer 10 is held at a temperature between 400 and 650 degrees Celsius and is being rotated by the wafer handling apparatus 104. A non-reactive gas flow is introduced into the sputtering chamber 103 and applying power to the magnetron 102 to activate the sputtering process for depositing a film onto the wafer.

### Magnetron

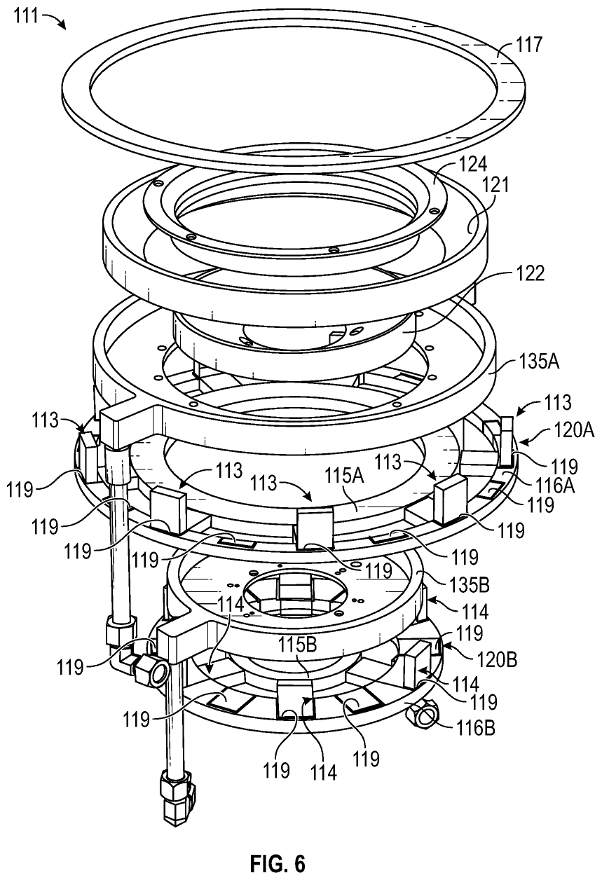

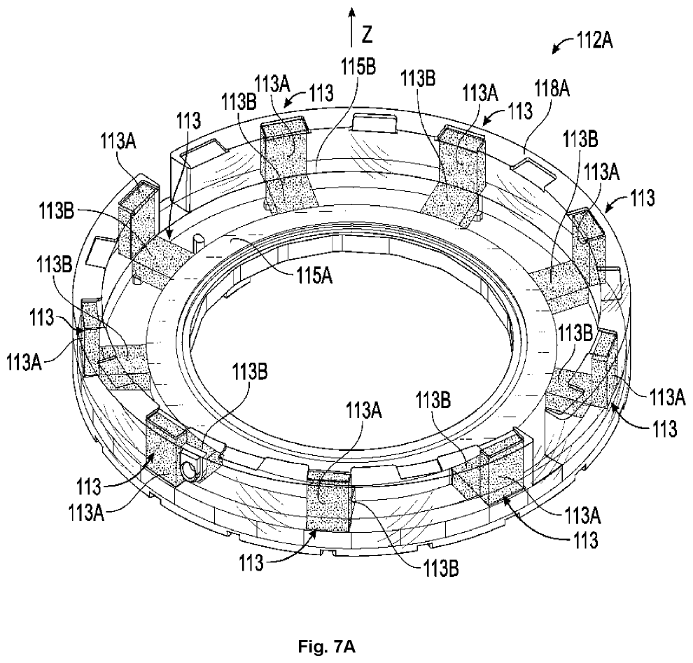

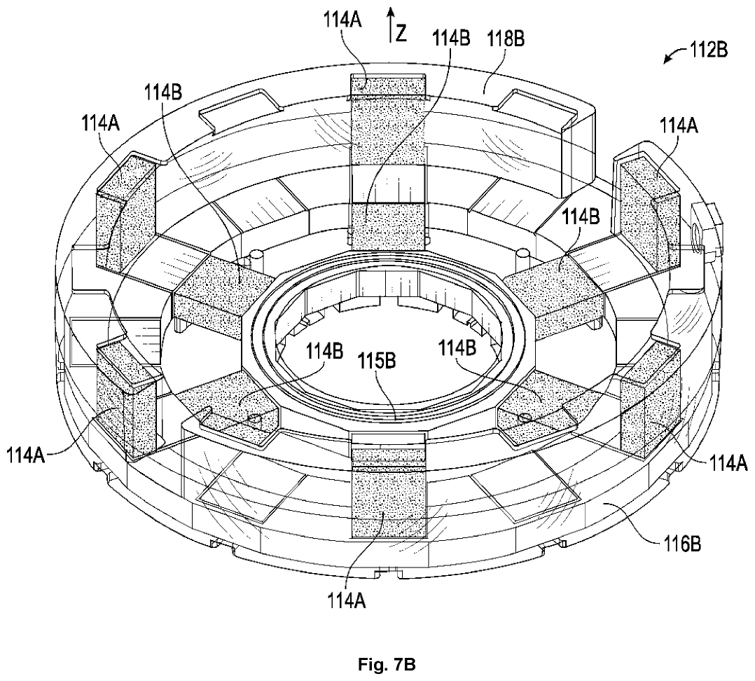

Referring to FIGS. 2-7, the magnetron 102 is shown defining a baseplate assembly 107 and a negatively charged target 120 (FIG. 4) with the target 120 resting within the baseplate assembly 107. The magnetron 102 further includes an internal assembly 111 situated directly beneath the target 120, the internal assembly 111 having an outer magnetic assembly 112A and an inner magnetic assembly 112B (FIG. 6) as well as an outer water jacket assembly 135A and an inner water jacket assembly 135B (FIG. 6). The magnetic assemblies 112A and 112B enable precise control of the magnetic field at the target 120 such that electrons are confined to the surface of the negatively charged target 120. The electrons enhance the ionization near the target 120 and newly formed ions are attracted towards the target 120 such that molecules are ejected from the target 120 and adhere to the wafer in the form of thin film. Control of the magnetic field by the magnetic assemblies 112A and 112B enables confinement of the electrons to particular areas of the target 120, thus enabling control of the sputtering process. In some embodiments, the magnetic assemblies 112A and 112B are each encased in a resin casing 118A and 118B (FIGS. 7A and 7B). As shown, the baseplate assembly 107 further includes a gas tower 108 (FIG. 4) extending through respective centers of the internal assembly 111 and the target 120 as well as a power feedthrough (not shown) for providing power to the magnetic assemblies 112A and 112B while the sputtering chamber 103 is under ultra-high vacuum. The magnetron 102 also includes a cooling plate 137 for cooling the power feedthrough 137 and the baseplate assembly 107 positioned underneath the internal assembly 111. In addition, a magnetron gas distribution system 132 is in fluid flow communication with the gas tower 108 when the magnetron 102 is assembled for introducing an inert gas into the sputtering chamber 103.

Referring to FIG. 4, the target 120 includes an outer concentric target 121 and an inner concentric target 122, and in some embodiments the target 120 is negatively biased. When in use within the sputtering chamber 103, positively charged gas ions are attracted towards the negatively charged outer concentric target 121 and inner concentric target 122. Specifically, the positively charged gas ions are attracted to the target 120. This causes material from the outer concentric target 121 and the inner concentric target 122 to be ejected from their respective surfaces by momentum transfer from the positively charged gas ions and adhere to the wafer 10 within the sputtering chamber 103. During the in-situ etch process, material is ejected from the target 120 and lightly sputtered onto the shield 175 of the sputtering chamber 103 when low power is applied to the magnetron 102, trapping etched contaminants underneath a layer of material. This prevents outgassing of contaminants during subsequent film deposition steps in which the sputtering chamber 103 is subjected to very high temperatures.

In some embodiments, to deposit an AlN film onto the wafer 10 during film deposition or onto the shield 175 of the sputtering chamber 103 during in-situ etching, the outer concentric target 121 and the inner concentric target 122 are comprised of aluminum. In some embodiments, the outer concentric target 121 and the inner concentric target 122 are separated by or otherwise electrically isolated from each other by an annular target shield 124. The annular target shield 124 is located between the outer concentric target 121 and the inner concentric target 122 to provide structural support and/or electrical isolation.

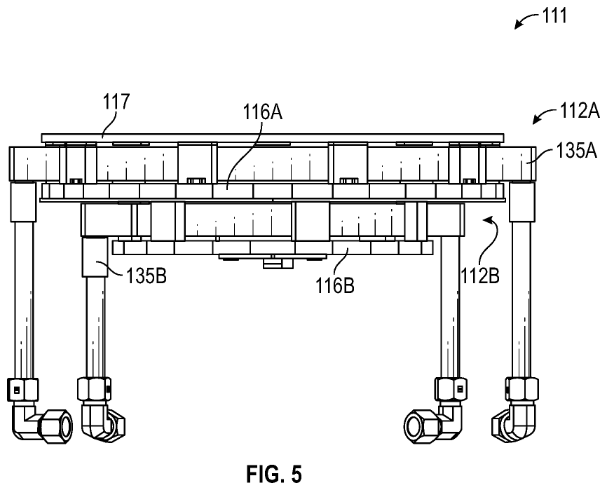

As discussed above and as shown in FIGS. 5 and 6, the internal assembly 111 further includes magnetic assemblies 112A and 112B configured to induce a magnetic field to confine negatively charged electrons to a surface of the outer and inner concentric targets 121 and 122, thus maintaining higher sputter rates by controlling the gas ionization near the target 120. The magnetic assemblies 112A and 112B mirror a concentric configuration of the target 120.

Referring to FIGS. 5-6B, the outer and inner magnet assemblies 112A and 112B are shown. As discussed above, the outer and inner magnet assemblies 112A and 112B induce a magnetic field within the sputtering chamber 103 (FIG. 3). The diameter of the inner magnet assembly 112B is less than that of the outer magnet assembly 112A, as shown in FIG. 6. In some embodiments, the diameter of the outer magnet assembly 112A is 11 inches and the diameter of the inner magnet assembly 112B is 7 inches; however, embodiments of the magnet assembly 112 are not limited to these diameters. The outer magnet assembly 112A, includes a plurality of magnet pairs 113 (FIG. 7A) arranged concentrically around a central axis Z. Similarly, the inner magnet assembly 112B, includes a plurality of magnet pairs 114 (FIG. 7B) arranged concentrically around a central axis Z.

Referring to FIGS. 7A and 7B, each magnet pair 113 of the outer magnet assembly 112A includes a respective vertically oriented magnet 113A aligned with the central axis Z and a respective horizontally oriented magnet 113B oriented perpendicular to the respective vertically oriented magnet 113A aligned with central axis Z. Similarly, each magnet pair 114 of the inner magnet assembly 112B includes a respective vertically oriented magnet 114A aligned with the central axis Z and a respective horizontally oriented magnet 114B oriented perpendicular to the respective vertically oriented magnet 114A aligned with central axis Z. Each magnet 113A, 113B, 114A and 114B is a permanent magnet.

In some embodiments shown in FIGS. 6-7B, the magnetic assemblies 112A and 112B define a magnetic circuit which is completed by connection between components of the outer magnet assembly 112A and the inner magnetic assembly 112B. In some embodiments, outer magnet assembly 112A includes a first outer pole piece 116A located underneath each vertically oriented magnet 113A and positioned externally relative to each horizontally oriented magnet 113B for structural support and for completion of a magnetic connection between each vertically oriented magnet 113A and each horizontally oriented magnet 113B. Further, the outer magnet assembly 112A includes a first inner pole piece 115A located internal to each horizontally oriented magnet 113B for additional structural support and for completion of a magnetic connection between each horizontally oriented magnet 113B of the outer magnet assembly 112A and each vertically oriented magnet 113A of the inner magnet assembly 112B. Similarly, the inner magnet assembly 112B includes a second outer pole piece 116B located underneath each vertically oriented magnet 114A and positioned externally relative to each horizontally oriented magnet 114B for completion of a magnetic connection between each vertically oriented magnet 114A and each horizontally oriented magnet 114B, as well as a second inner pole piece 115B located internal to each horizontally oriented magnet 114B for structural support and completion of the magnetic connection. In some embodiments, an upper pole piece 117 is included above the outer magnet assembly 112A for completion of the magnetic circuit. In some embodiments, each pole piece including the upper pole piece 117, first and second outer pole pieces 116A and 116B, and first and second inner pole pieces 115A and 115B includes a plurality of self-alignment indentations 119 for receipt and alignment of each magnet 113A, 113B, 114A and 114B. Each pole piece 117, 115A, 115B, 116A and 116B forces each magnet 113A, 113B, 114A and 114B to magnetically align with the pole pieces 117, 115A, 115B, 116A and 116B, improving magnetic uniformity and magnetic flux through the permanent magnets 113A, 113B, 114A and 114B.

For formation of the outer magnet assembly 112A, each magnet pair 113 of the outer magnet assembly 112A is encased in a nonconductive resin 118A (not shown), to provide for structural support as well as to prevent the magnet pairs 113 from shifting. Similarly, for formation of the inner magnet assembly 112B, each magnet pair 114 of the inner magnet assembly 112B is encased in nonconductive resin 118B to provide structural support as well as to prevent the magnet pairs 114 from shifting. Further, in some embodiments, each pole piece 117, 115A, 115B, 116A and 116B are encapsulated within the nonconductive resin 118A and 118B.

When low AC power (100-350 W) is applied to the magnetron 102 for in-situ etching of wafer 10, very light sputtering of material from the target 120 occurs such that etched contaminants are trapped against the shield 175 of the sputtering chamber 103 such that they are not re-deposited back onto the wafer 10 or released into the sputtering chamber 103 during subsequent film deposition. For film deposition, 3-5 kW of AC power is applied to the magnetron 102 for full deposition of material from the target 120 onto the wafer 10.

### Wafer Handling Apparatus

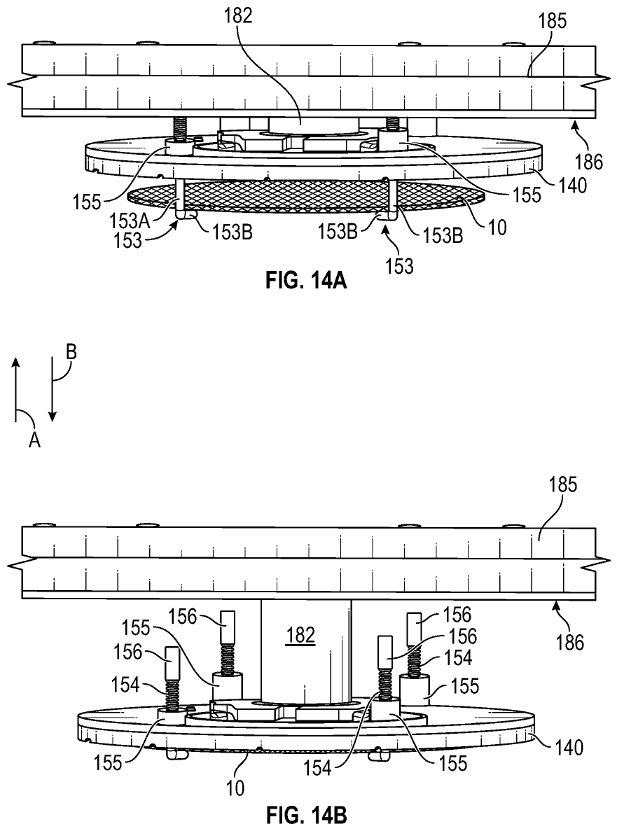

Referring to FIGS. 2 and 8-16, the wafer handling apparatus 104 is shown including the wafer chuck 140, the wafer chuck 140 being defined at a lower end of a vertical rod 182 and operable to receive the wafer 10. In some embodiments, the wafer chuck 140 is associated with the thermoelectric assembly 145 which is operable for delivering heat to the wafer 10 as well as power. In particular, the thermoelectric assembly 145 is operable for applying a negative potential in the form of an RF bias to the wafer 10 through the wafer chuck 140 such that the wafer 10 is negatively charged. This allows ions to be attracted to the wafer 10 for plasma etching of contaminants from the surface of the wafer 10. In some embodiments, the vertical rod 182 and wafer chuck 140 are of a conductive material. Thermoelectric assembly 145 applies the RF bias to the vertical rod 182, which is in electrical communication with the wafer chuck 140 such that the RF bias is applied to the wafer 10 when the wafer 10 is coupled against the wafer chuck 140. As shown, the vertical rod 182 is in association with a feedthrough plate 180 by a feedthrough 181, a lifting assembly 172 for lifting or lowering the feedthrough plate 180 and consequently the wafer chuck 140 in an axial direction A or B relative to the main plate 185, and a rotational assembly 170 in communication with the feedthrough 181 and vertical rod 182 for rotation of the vertical rod 182 and wafer chuck 140. As shown specifically in FIG. 14A, the lifting assembly 172 is operable for lifting the wafer chuck 140 into a “wafer loading” position such that the plurality of pin assemblies 150 disposed around the wafer chuck 140 open and receive a wafer 10. As shown in FIG. 14B, the lifting assembly 172 is also operable for lowering the wafer chuck 140 into the “wafer processing” position such that the plurality of pin assemblies 150 secure the wafer 10 against an underside of the wafer chuck 140.

The wafer handling apparatus 104 further includes the thermoelectric assembly 145 and a wafer chuck gas assembly 146 in association with the feedthrough 181, vertical rod 182 and wafer chuck 140 for introducing power (in the form of a negative potential RF bias) and gas to the wafer chuck 140. The wafer handling apparatus 104 is configured to be positioned above the target 120 of the magnetron 102 (FIG. 4) for in-situ etching of the wafer 10 as well as subsequent physical vapor deposition of material onto the wafer 10. As shown, the shield 175 is included between the target 120 of the magnetron 102 and the main plate 185 of the wafer handling apparatus 104 enclosing the sputtering chamber 103.

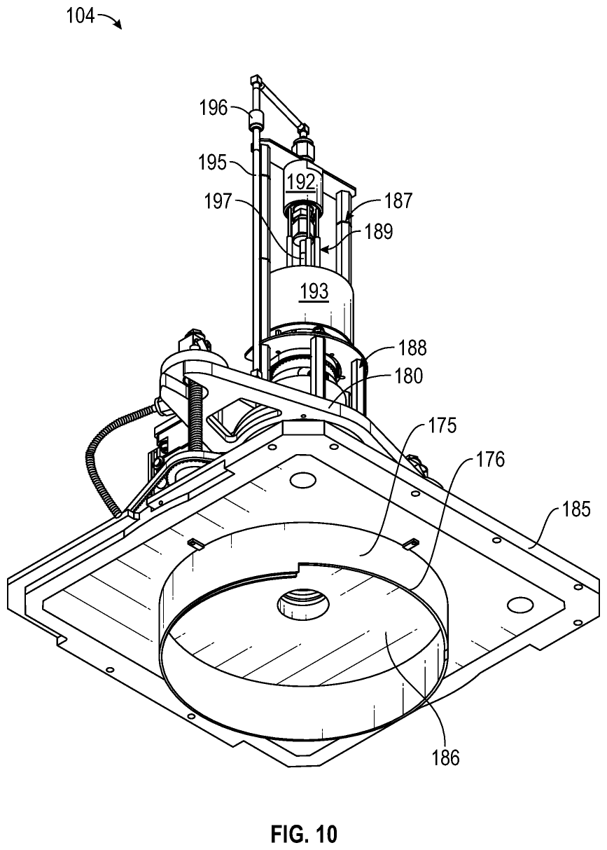

Referring to FIGS. 2, 14A and 14B, in some embodiments, the plurality of pin assemblies 150 include an “L”-shaped pin 153 including a vertical section 153A and a lateral section 153B. As shown specifically in FIG. 14A, each vertical section 153A includes a pin cap 156 which, while in the “wafer loading” position, contacts an underside 186 (FIG. 10) of the main plate 185. Each pin assembly 150 is disposed through a respective securing piece 155, each securing piece 155 being engaged to a circumferential edge of the wafer chuck 140. In some embodiments, each vertical section 153A of the pin 153 is sheathed by a spring 154 located between the pin cap 156 and the securing piece 155, allowing each pin assembly 150 to clutch the wafer 10 against the underside of the wafer chuck 140 while in the “wafer processing” position, as shown in FIG. 14B. Referring to FIG. 14A, when the vertical rod 182 and the wafer chuck 140 are lifted to the “wafer loading” position, each pin cap 156 contacts the underside 186 of the main plate 185 and compresses each spring 154 such that each respective pin 153 is lowered into the “wafer loading” position which maximizes a transfer gap between the lateral section 156 of each pin 153 and the underside of the wafer chuck 140 such that the wafer 10 may be inserted or removed. As shown in FIG. 14B, the vertical rod 182 and wafer chuck 140 are lowered out of the loading position, the pin cap 156 no longer contacts the underside 186 of the main plate 185 and each spring 154 will be allowed to assume a decompressed state and lift each pin 153 into the “wafer processing” position. In this “wafer processing” position, the wafer 10 is clamped in place to the underside of the wafer chuck 140 for processing by the lateral section 153B of each pin assembly 150.

FIGS. 11-13 illustrate the wafer chuck 140 defined at a lower end of the vertical rod 182. As shown, the wafer chuck 140 includes a plurality of pin assemblies 150 which are operable for receiving and securing the electronic wafer 10 against an underside of the wafer chuck 140. In some embodiments, the wafer chuck 140 is in electrical communication with the thermoelectric assembly 145 for applying heat and negative potential in the form of RF bias to the wafer 10, and may include one or more heating elements (not shown) for generating heat. As shown in FIG. 15, the wafer chuck 140 includes an upper shield 142 defined above the wafer chuck component 141, a lower shield 143 defined below the wafer chuck component 141, and an outer covering 144 which encapsulates the wafer chuck component 141, all which serve the purpose of conserving heat and directing heat towards the wafer chuck component 141 and consequently, the electronic wafer 10. The wafer chuck 140 also includes a plurality of spacers 148 for electrical and thermal insulation. In some embodiments each of the plurality of spacers 148 is of a thermally and electrically insulating material such as ceramic.

Referring directly to FIG. 16, the wafer chuck gas assembly 146 comprises a gas inlet 194 in fluid flow communication with an external gas source (not shown) for introduction of a non-reactive gas, usually argon, for plasma etching and physical vapor deposition onto the wafer 10. The gas inlet 194 transfers gas from the external source (not shown) to a gas line 195. In some embodiments, a cryogenic break 196 is included along the gas line 195 to provide a safety measure if the gas line 195 is broken or otherwise damaged. As shown, the gas line 195 terminates at a rotary union 192 for maintaining fluid flow communication to the heated chuck 140 while the heated chuck 140 and vertical rod 182 are rotated by the rotational assembly 170. The rotary union 192 and gas line 195 are supported above the feedthrough plate 180 by the upper frame 187. A secondary gas line 197 connects the rotary union 192 to the wafer chuck 140 and in some embodiments extends downward through the vertical rod 182 to terminate in the one or more small apertures 147 (FIG. 13) defined on the underside of the wafer chuck 140. The introduction of gas at the wafer chuck 140 while heat is concurrently applied to the wafer 10 allows for improved heat distribution uniformity across the wafer 10.

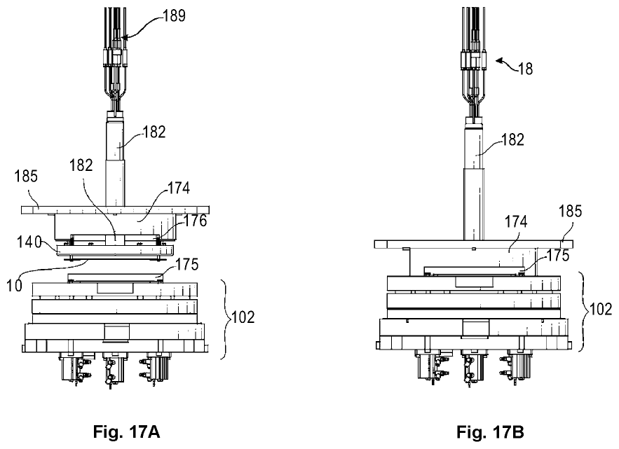

Referring to FIGS. 17A and 17B, the wafer chuck 10 is disposed above the target 120 of the magnetron 102 defining the sputtering chamber 103. The shield 175 is secured underneath the main plate 185 of the wafer handling apparatus 104 and encapsulates the wafer chuck 10 such that an environment within the sputtering chamber 103 is controlled in terms of gas flow rate and pressure, as specifically shown in the assembled view of FIG. 17B. As shown, the shield 175 includes the slot 176 for insertion of a wafer 10 when in the “wafer loading” position. While in the “wafer processing” position, when the wafer 10 is being processed within the sputtering chamber 103, the slot 176 is sealed by a slot guard 175 which is operable to move in and out of position to allow the wafer 10 to be inserted and removed when the wafer chuck 140 is in the “wafer loading” position and to seal the slot 176 when the wafer chuck 140 is in the “wafer processing” position.

### In-Situ Etching Methodology

In one method of etching surface contaminants from a wafer 10 prior to film deposition using the sputtering chamber 103, the wafer 10 is first received and lowered into the sputtering chamber 103 by the wafer handling apparatus 102. The wafer 10 is then subjected to an in-situ etching process in which a non-reactive gas (Ar and N₂) is introduced into the sputtering chamber 103 and a negative potential is applied to the wafer 10 by thermoelectric assembly 145 and the magnetron 102. It should be noted that during in-situ etching, the power applied to the magnetron 102 is very low compared to typical sputtering applications, preferably ranging between 100-350 W. Following the in-situ etching process, gas is purged from the sputtering chamber 103, the wafer 10 is heated, and the wafer 10 is subjected to a sputtering process in which high AC power (3-5 kW) is applied to the magnetron 102.

The wafer 10 is received by a plurality of pin assemblies 150 and clamped against a wafer chuck 140 of the wafer handling apparatus 104 before being lowered into the sputtering chamber 103 and above the magnetron 102. In some embodiments, the wafer 10 is inserted into the sputtering chamber 103 through the slot 176 and received by the plurality of pin assemblies 150. Once received, the vertical rod 182 lifts the wafer chuck 140 to a maximum height relative to the main plate 185 into a “wafer loading” position by the lifting assembly 172. While in the “wafer loading” position, the plurality of pin assemblies 150 are operable to open and receive the wafer 10, as shown in FIG. 14A. The vertical rod 182 lowers the wafer chuck 10 to a variable “wafer processing” position relative to the main plate 185 within the sputtering chamber 103, as shown in 14B. In this position, the plurality of pin assemblies 150 physically clamp the wafer 10 against an underside of the wafer chuck 140.

An inert gas is introduced into the sputtering chamber 103 via the gas tower 108 of the magnetron 102 and the gas assembly 146 of the wafer chuck 140. In some embodiments, the gas is argon (Ar) and nitrogen (N₂) and are introduced at respective rates of 5-10 cm³/min and 10-20 cm³/min. The atmosphere within the sputtering chamber 103 is controlled such that the inert gas is separated into positively charged ions and negatively charged electrons, thereby creating a plasma.

A negative potential in the form of an RF bias (100-300 W) is applied to the wafer 10 via the wafer chuck 140 in association with a thermoelectric assembly 145 and low AC power (100-350 W) is simultaneously applied to the magnetron 102 to negatively charge the target 120 in a “light sputtering” operation. As discussed above, the negative RF bias applied to the wafer 10 attracts ions towards the surface of the wafer 10, etching away contaminants that are released into the sputtering chamber 103. Similarly, application of negative potential to the magnetron 102 attracts ions from the plasma towards the target 120 of the magnetron, effectively lightly sputtering material off of the target 120 simultaneously with the etching of the wafer 10. This simultaneous application of power to both the wafer 10 and the magnetron 102 prevents etched contaminants from landing on and/or adhering to the wafer 10 or target 120 of the magnetron 102. Etched contaminants as well as sputtered material from the target 120 are forced to adhere to the shield 175 of the sputtering chamber 103, trapping contaminants underneath a light layer of material from the target 120. This “trapping” mechanism prevents outgassing of oxygen and contaminants from the shield 175 of the sputtering chamber 103 during subsequent film deposition, which can subject the sputtering chamber 103 to extremely high temperatures.

A gas is purged from the sputtering chamber 103. This can be done by conventional purging methods including but not limited to flooding the sputtering chamber 103 with non-reactive gas several times to sweep impurities from the environment within the sputtering chamber. In one particular embodiment, the non-reactive gas is N₂, purged 2-3 times. After etching of the wafer 10, the wafer 10 is heated to a temperature between 300 and 500 degrees Celsius. Heat is applied to the wafer 10 via the thermoelectric assembly 145 of the wafer chuck 140. In some embodiments, as discussed above, a gas is introduced at the wafer chuck 140 by the wafer chuck gas assembly 146 while the wafer 10 is concurrently being heated to allow for uniformity of heat distribution across the wafer 10. The thermoelectric assembly 145 continues to maintain a temperature of the wafer 10 at a temperature within the range of 300-500 degrees Celsius through the sputtering process.

The magnetron 102 applies a sputtering process to the wafer 10. Inert gas is introduced into the sputtering chamber 103 via the gas tower 108 of the magnetron 102. In some embodiments, the gas is argon (Ar) and nitrogen (N₂) and are introduced at respective rates of 5-10 cm³/min and 10-20 cm³/min. The atmosphere within the sputtering chamber 103 is controlled such that the inert gas is separated into positively charged ions and negatively charged electrons, thereby creating a plasma. AC power in a range between 3-5 kW is applied to the magnetron 102 to negatively charge the target 120. The positively charged ions introduced are accelerated into the negatively biased target 120. The positively charged ions are accelerated and strike the negatively charged target 120 with enough force to dislodge and eject microscopic molecules of material from the target 120. Such molecules of material then condense onto the wafer surface. The magnetic field generated by the magnet assemblies 112A and 112B of the internal assembly 111 aids in this process by confining negatively charged electrons at the surface of the target 120. The confined negatively charged electrons attract the positively charged ions to the surface of the target 120, which then dislodge molecules of target material. In some embodiments, the magnetic field is tuned such that the negatively charged electrons are optimally arranged on the target 120 for uniform deposition and faster deposition rates of molecules from the target 120 onto the wafer 10.

In some embodiments, the system 100 is in communication with a computing system for control of the magnetron 102 and the wafer handling apparatus 104. The computing system can in some embodiments receive feedback from the magnetron 102 and the wafer handling apparatus 104 to adjust parameters for real-time control of the wafer 140 including but not limited to: wafer temperature, wafer position, etch quality, parameters indicative of magnetron function, and data related to film thickness, uniformity, and/or integrity. The computing system is also operable to store and execute instructions for control of the magnetron 102 and the wafer handling apparatus 104, and in particular, to control the rotational assembly 170 and lifting assembly 172 of the wafer handling apparatus 104 and to control the target 120 and magnet assemblies 112A and 112B of the magnetron 102. In some embodiments, the computing system is also operable to control the RF bias applied to the wafer 10 by the thermoelectric assembly 145 and to control a flow of gas from both the gas assembly 146 of the wafer handling apparatus 104 and the gas distribution system 132 of the magnetron 102.

### Results and Test Data

The system 100 is able to achieve a full width at half maximum (FWHM) of the rocking curve of about 1.5 degree with application of the in-situ etching process, which is unprecedented compared to previously reported results and compared to a FWHM of separately-etched wafers on the same deposition equipment. The FWHM value achieved by the system 100 with application of the in-situ methodology 200 is highly competitive with conventional systems that require separate etching and film deposition equipment.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

What is claimed is:

1. A method for in-situ etching of a wafer prior to physical vapor deposition, the method comprising:
providing a sputtering chamber;
placing the wafer into said sputtering chamber; and
applying a first negative potential to the wafer in said sputtering chamber while simultaneously applying a second negative potential to a sputtering target in said sputtering chamber.

2. The method of claim 1, further comprising depositing a film onto the wafer using a physical vapor deposition process within said sputtering chamber by applying a third negative potential to the sputtering target.

3. The method of claim 1, further comprising depositing an aluminum nitride film using the sputtering target.

4. The method of claim 1, wherein the second negative potential applied to the sputtering target is between 100 watts and 350 watts.

5. The method of claim 4, wherein the first negative potential applied to the wafer is between 100 watts and 300 watts.

6. The method of claim 1, wherein material is sputtered from the sputtering target onto a shield of said sputtering chamber during the application of the second negative potential to the sputtering target and material is ejected from the wafer onto the shield of said sputtering chamber during the application of the first negative potential to the wafer.

7. The method of claim 1, further comprising applying heat to the wafer, wherein a temperature of the heat applied to the wafer is between 300 degrees Celsius and 500 degrees Celsius.

8. The method of claim 1, further comprising rotating the wafer.

9. A method for in-situ etching of a wafer prior to physical vapor deposition, the method comprising:
providing a sputtering chamber, said sputtering chamber being collectively defined by a wafer handling apparatus and a magnetron;
placing the wafer into said sputtering chamber;
introducing a gas into said sputtering chamber such that the gas is separated into a plasma, wherein the plasma includes gas ions; and
applying a first negative potential to the wafer using a wafer chuck of the wafer handling apparatus while simultaneously applying a second negative potential to a sputtering target of the magnetron, wherein simultaneous application of the first negative potential to the wafer and the second negative potential to the sputtering target causes gas ions to eject material from the wafer and the sputtering target of the magnetron such that ejected material from the wafer and the sputtering target is collected onto a shield defined by said sputtering chamber.

10. The method of claim 9, further comprising depositing a film onto the wafer using a physical vapor deposition process within said sputtering chamber by applying a third negative potential to the sputtering target of the magnetron.

11. The method of claim 9, further comprising depositing an aluminum nitride film using the sputtering target of the magnetron.

12. The method of claim 9, wherein the second negative potential applied to the sputtering target of the magnetron is between 100 watts and 350 watts.

13. The method of claim 12, wherein the first negative potential applied to the wafer is between 100 watts and 300 watts.

14. The method of claim 9, further comprising purging the plasma from said sputtering chamber prior to depositing a film onto the wafer using a physical vapor deposition process.

15. The method of claim 9, further comprising applying heat to the wafer, wherein a temperature of the heat applied to the wafer is between 300 degrees Celsius and 500 degrees Celsius.

16. The method of claim 9, further comprising rotating the wafer.

17. A method for in-situ etching of a wafer prior to physical vapor deposition, the method comprising:
providing a sputtering chamber, said sputtering chamber being collectively defined by a wafer handling apparatus and a magnetron;
placing the wafer into said sputtering chamber;
introducing a gas into said sputtering chamber such that the gas is separated into a plasma, wherein the plasma includes gas ions;
applying a first negative potential to the wafer using a wafer chuck of the wafer handling apparatus while simultaneously applying a second negative potential to a sputtering target of the magnetron, wherein simultaneous application of the first negative potential to the wafer and second negative potential to the sputtering target causes gas ions to eject material from the wafer and the sputtering target of the magnetron such that ejected material from the wafer and the sputtering target is collected onto a shield defined by said sputtering chamber;
purging the plasma from said sputtering chamber; and
depositing a film onto the wafer using a physical vapor deposition process within said sputtering chamber by applying a third negative potential to the sputtering target of the magnetron.

18. The method of claim 17, further comprising depositing an aluminum nitride film using the sputtering target of the magnetron.

19. The method of claim 17, wherein the second negative potential applied to the sputtering target of the magnetron is between 100 watts and 350 watts.

20. The method of claim 19, wherein the first negative potential applied to the wafer is between 100 watts and 300 watts.
